(19) United States
(12) Patent Application Publication
(10) Pub. No.: US 2010/0270570 A1
(43) Pub. Date: Oct. 28, 2010

(54) LIGHT EMITTING ELEMENT

(76) Inventors: Wei-Kang CHENG, Lung Tan (TW); Yi-Sheng Ting, LungTan (TW); Shyi-Ming Pan, Lung Tan (TW)

Correspondence Address: SINORICA, LLC, 2275 Research Blvd., Suite 500, ROCKVILLE, MD, 20850, US

(21) Appl. No.: 12/558,849

(22) Filed: Sep. 14, 2009

(30) Foreign Application Priority Data
Apr. 24, 2009 (TW) 098113712

(51) Int. Cl. H01L 33/00

(52) U.S. Cl. 257/98; 257/E33.061

(57) ABSTRACT

The present invention provides a light emitting element comprising a first substrate, a light emitting unit disposed on the first substrate, at least a selective reflection layer disposed on an emitting side of the light emitting unit so that a light of a first color emitted from the light emitting unit passes through the selective reflection layer, and a fluorescent layer disposed on the emitting side of the light emitting unit and converting the light of the first color passing therethrough into a light of a second color, wherein a light of a mixed color is formed by the lights of the first and second color and only the light of the second color is reflected by the selective reflection layer.

### BACKGROUND OF THE INVENTION

1. Field of the Invention

The present invention is related to a light emitting element, more particularly, to a light emitting element having a selective reflection layer.

2. Description of the Prior Art

LED(Light Emitting Diode) is one of the most competetive products in the optoelectronic industry of Taiwan. Taiwan has a complete supply chain for LED. Many domestic manufacturer egage in manufacturing of Gallium arsenide and die, and packaging, wherein United Epitaxy Company, LTD is one of the earliest company manufacturing high power LED. Taiwan has become the largest supply country for visible-light LED around the world and also leads in manufacturing of high-power LEDs. The scale of LED manufacturing in Taiwan only fall behind Japan and US, and ranks 3^{rd} in the global LED market. Since Taiwan has a complete supply chain for LED, comprising die saw, package, application and the research and development of Gallium arsenide, Taiwan has the potential to be the largest manufacturing country of LED.

LED is a semiconductor element and has been popularly used in pointers and displays of many 3C products due to its small volume, long lifetime and low power consumption. The application of LED is enhanced by the emergence of blue LED in Japan, 1994 which makes it possible to display colors by combining red, blue and green LEDs. Furthermore, the yield improvement of LED decreases the manufacturing cost, which establishes a prosperous LED market.

In order to enhance the efficiency of LED, the present invention provides a light emitting element having a selective reflection layer through which light of a first color emitted by a light emitting diode passes and by which light of a second color converted by a fluorescent layer is reflected. Thus, the light of the first and second color can be mixed to enhance the efficiency of LED.

### SUMMARY OF THE INVENTION

The present invention provides a light emitting element comprising a first substrate, a light emitting unit disposed on the first substrate, at least a selective reflection layer disposed on an emitting side of the light emitting unit so that a light of a first color emitted from the light emitting unit passes through the selective reflection layer, and a fluorescent layer disposed on the emitting side of the light emitting unit and converting the light of the first color passing therethrough into a light of a second color, wherein a light of a mixed color is formed by the lights of the first and second color and only the light of the second color is reflected by the selective reflection layer.

### DETAILED DESCRIPTION OF PREFERRED EMBODIMENTS

FIG. 1 is a diagram shown a light emitting element according to one embodiment of the invention. The light emitting element 1 includes a first substrate 10, a light emitting unit, at least a selective reflection layer 14 and a fluorescent layer 16. The light emitting unit includes at least a light emitting diode 12. The selective reflection layer 14 is disposed on one side of the light emitting diode of the light emitting unit. The selective reflection layer 14 has a thickness ranging from 500 nm to 500000 nm. The fluorescent layer 16 is disposed on the first substrate 10 and covers the light emitting diode 12 of the light emitting unit. The light emitting diode 12 emits light of a first color which is blue in this embodiment. The light of the first color passes through the selective reflection layer 14 and reaches the fluorescent layer 16. The fluorescent layer 16 converts the light of the first color into light of a second color which is yellow in this embodiment. The light of the first and second color combine to form light of a mixed color. The light of the second color may go toward the light emitting diode 12 and then may be reflected by the selective reflection layer 14, which helps to mix the light of the first and second color. This will enhance the efficiency of the LED.

The light emitting diode 12 includes a second substrate 120, a first semiconductor layer 121, a light emitting layer 123, a second semiconductor layer 125, at least a first electrode 127 and at least a second electrode 129. The first semiconductor layer 121 is disposed on the first substrate 10. The light emitting layer 123 is disposed on the first semiconductor layer 121. The second semiconductor layer 129 is disposed on the light emitting layer 123. The first electrode 127 is disposed on the first semiconductor layer 121. The second electrode 129 is disposed on the second semiconductor layer 125. The selective reflection layer 14 is disposed on the second semiconductor layer 125, the first electrode 127 and the second electrode 129. Both the first semiconductor layer 121 and the first electrode 127 are P type while the second semiconductor layer 127 and the second electrode 129 are N type. Alternatively, both the first semiconductor layer 121 and the first electrode 127 are N type while the second semiconductor layer 127 and the second electrode 129 are P type. For enhancement of the efficiency of LED, a reflection layer 128 is disposed on the first semiconductor layer 121. In this embodiment, the reflection layer 128 is disposed between the first semiconductor layer 121 and the first substrate 10. Alternatively, the reflection layer 128 may be disposed between the first semiconductor layer 121 and light emitting layer 123.

FIG. 2 is a diagram showing the selective reflection layer according to one embodiment of the invention. The selective reflection layer 14 includes dielectric layers 141 having at least two different thicknesses. For example, the selective reflection layer 14 may include a first, second and third dielectric layers. The first and third dielectric layers have a thickness A while the second dielectric layer has a thickness B. Furthermore, each dielectric layer is made of a different material from its adjacent dielectric layer. For example, the first and third dielectric layers are made of material C while the second dielectric layer is made of material D. The materials of the dielectric layers may be two of the following: SiO₂, TiO₂, TaO, ZnO, NbO, AIN, InN, TnN and MgN.

FIG. 3 is a diagram showing a light emitting element according to another embodiment of the invention. The difference between the light emitting elements showing in FIGS. 1 and 3 is that, in FIG. 3, the light emitting diode 12 is disposed upside down on the first substrate 10 so that it becomes a Flip-Chip LED. The first semiconductor layer 121 is disposed on the second substrate 120. The light emitting layer 123 is disposed on the first semiconductor layer 121. The second semiconductor layer 125 is disposed on the light emitting layer 123. The first electrode 127 is disposed on the first semiconductor layer 121. The second electrode 129 is disposed on the second semiconductor layer 125. The first and second electrodes 127 and 129 are coupled to the first substrate 10 through metal contacts 124 and 126. The selective reflection layer 14 is disposed on the second substrate 120. Alternatively, the second substrate may be removed to prevent stress problem so that the selective reflection layer 14 is disposed on the first semiconductor layer 121. Both the first semiconductor layer 121 and the first electrode 127 are P type while the second semiconductor layer 127 and the second electrode 129 are N type. Alternatively, both the first semiconductor layer 121 and the first electrode 127 are N type while the second semiconductor layer 127 and the second electrode 129 are P type. For enhancement of the efficiency of LED, a reflection layer 128 is disposed on the second semiconductor layer 125. In this embodiment, the reflection layer 128 is disposed between the second semiconductor layer 125 and the second substrate 129.

FIG. 4 is a diagram showing a light emitting element according to another embodiment of the invention. The difference between the light emitting element 1 shown in FIGS. 3 and 4 is that the substrate 10 in the FIG. 4 is in a shape of a bowl. This focuses the light from the light emitting diode 12 and enhance the efficiency of LED. The first substrate 10 shown in FIG. 1 could be also in the shape of a bowl.

FIG. 5 is a diagram showing a light emitting element according to another embodiment of the invention. The difference between the light emitting element 1 shown in FIGS. 1 and 5 is that the light emitting diode 12 in FIG. 5 is an AC LED.

The AC LED includes light emitting diodes 12 coupled to each other. Each light emitting diode 12 includes a first semiconductor layer 121, a light emitting layer 123, a second semiconductor layer 125, a first electrode 127 and a second electrode 129. The first semiconductor layer 121 is disposed on the first substrate 10. The light emitting layer 123 is disposed on the first semiconductor layer 121. The second semiconductor layer 129 is disposed on the light emitting layer 123. The first electrode 127 is disposed on the first semiconductor layer 121. The second electrode 129 is disposed on the second semiconductor layer 125. Dielectric layers 122 are disposed between the light emitting diodes 12 and the second electrode 129 of each light emitting diode 12 is coupled to the first electrode 127 of its adjacent light emitting diode 12. For enhancement of the efficiency of LED, a reflection layer 128 is disposed between the first semiconductor layer 121 and the first substrate 10. Alternatively, the reflection layer 128 may be disposed between the first semiconductor layer 121 and the light emitting layer 123.

Alternatively, the substrate 10 may be in a shape of a bowl, as shown in FIG. 4.

FIG. 6 is a diagram showing a light emitting element according to another embodiment of the invention. The difference between the light emitting element 1 shown in FIGS. 1 and 6 is that, in FIG. 6, the first semiconductor layers 121 are disposed on the second substrate 120. The first and second electrodes 127 and 129 are coupled to the first substrate 10 through metal contacts 124 and 126. The selective reflection layer 14 is disposed on the second substrate 120. For enhancement of the efficiency of LED, a reflection layer 128 is disposed between the second semiconductor layer 125 and the second electrode 129. Alternatively, the substrate 10 may be in a shape of a bowl, as shown in FIG. 4.

In conclusion, the present invention provides a light emitting element having a selective reflection layer through which light of a first color emitted by a light emitting diode passes and by which light of a second color converted by a fluorescent layer is reflected. Thus, the light of the first and second color can be mixed to enhance the efficiency of LED. Further, the first substrate may be in a shape of a bowl, which help to focus the light from the light emitting diode.

### BRIEF DESCRIPTION OF DRAWINGS

FIG. 1 is a diagram shown a light emitting element according to one embodiment of the invention.

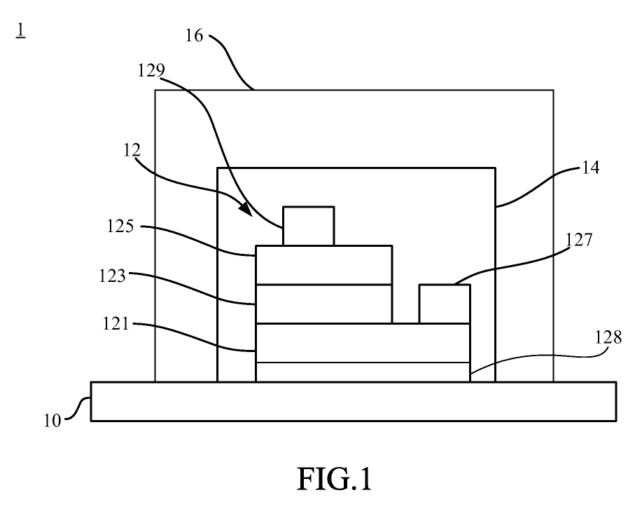

FIG. 2 is a diagram showing the selective reflection layer according to one embodiment of the invention.

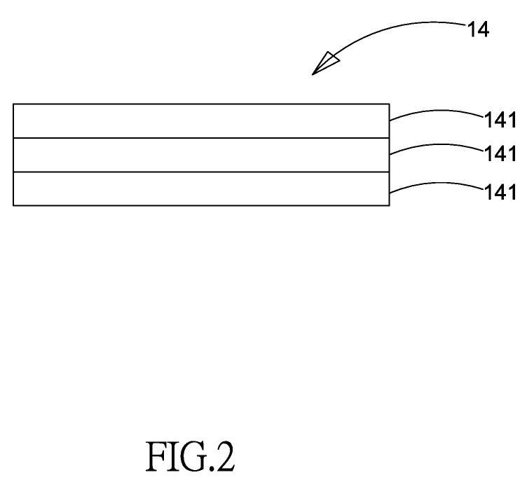

FIG. 3 is a diagram showing a light emitting element according to another embodiment of the invention.

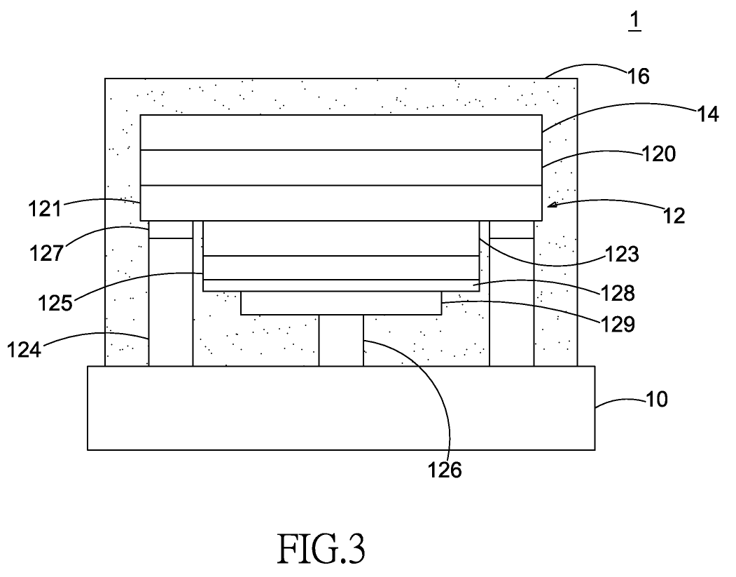

FIG. 4 is a diagram showing a light emitting element according to another embodiment of the invention.

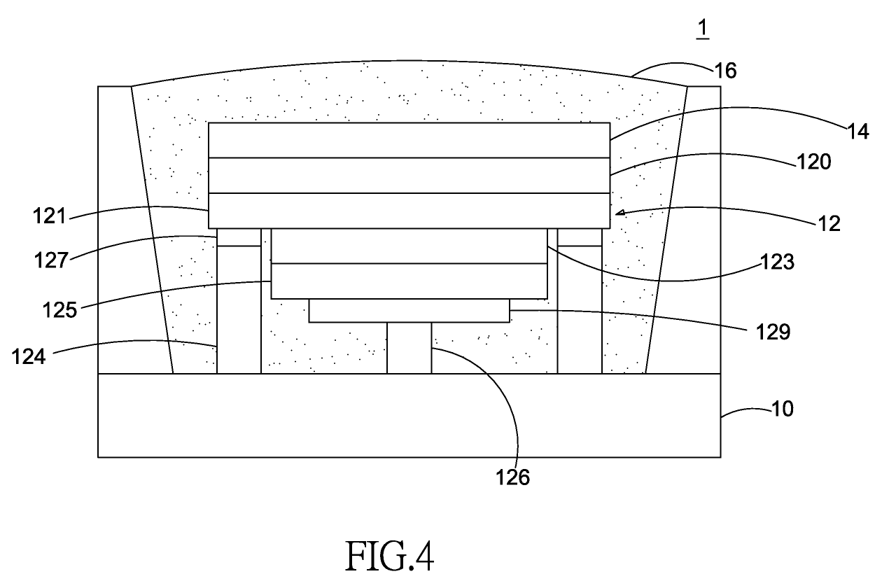

FIG. 5 is a diagram showing a light emitting element according to another embodiment of the invention.

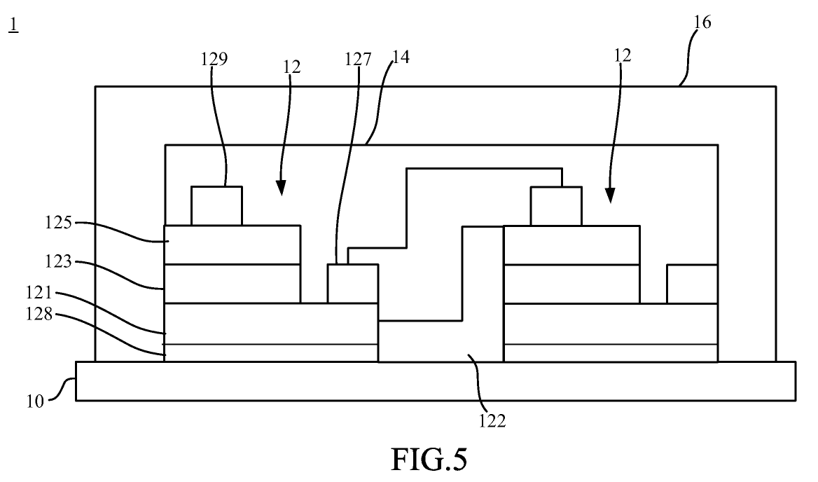

FIG. 6 is a diagram showing a light emitting element according to another embodiment of the invention.

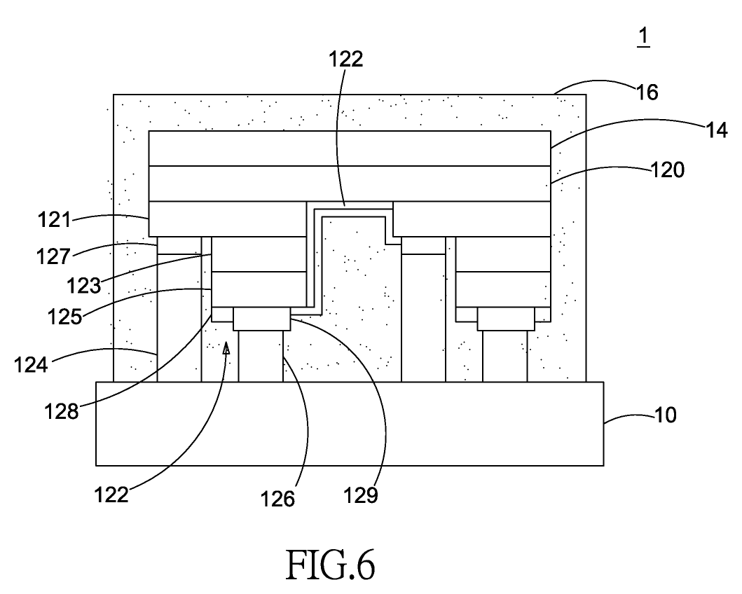

What is claimed is:

1. A light emitting element comprising:
a first substrate;
a light emitting unit disposed on the first substrate;
at least a selective reflection layer disposed on an emitting side of the light emitting unit so that a light of a first color emitted from the light emitting unit passes through the selective reflection layer; and
a fluorescent layer disposed on the emitting side of the light emitting unit and converting the light of the first color passing therethrough into a light of a second color, wherein a light of a mixed color is formed by the lights of the first and second color and the light of the second color is reflected by the selective reflection layer.

2. The light emitting element as claimed in claim 1, wherein a thickness of the selective reflection layer ranges from 500 nm to 500000 nm.

3. The light emitting element as claimed in claim 1, wherein the selective reflection layer comprises a Bragg grating.

4. The light emitting element as claimed in claim 1, wherein the selective reflection layer comprises a plurality of dielectric layers comprising two of the following materials: SiO₂, TiO₂, TaO, ZnO, NbO, AIN, InN, TnN and MgN, and having at least two different thicknesses, and the material of one of the dielectric layers is different from the material of its adjacent layer.

5. The light emitting element as claimed in claim 1, wherein the light emitting unit comprises at least a light emitting diode.

6. The light emitting element as claimed in claim 5, wherein the light emitting diode comprises:
a first semiconductor layer;
a light emitting layer disposed on the first semiconductor layer;
a second semiconductor layer disposed on the light emitting layer;
at least a first electrode disposed on the first semiconductor layer; and
at least a second electrode disposed on the second semiconductor layer.

7. The light emitting element as claimed in claim 6, wherein the first semiconductor layer is disposed on the first substrate, and the selective reflection layer is disposed on the second semiconductor layer, the first electrode and the second electrode.

8. The light emitting element as claimed in claim 7 further comprising a reflection layer disposed on the first semiconductor layer.

9. The light emitting element as claimed in claim 6, wherein the first and second electrodes are coupled to the first substrate through a metal contact, the selective reflection layer is disposed on the first semiconductor layer, and a second substrate is disposed between the first semiconductor layer and the selective reflection layer.

10. The light emitting element as claimed in claim 9 further comprising a reflection layer disposed on the second semiconductor layer.

11. The light emitting element as claimed in claim 1, wherein the light emitting unit is an AC light emitting diode comprising a plurality of light emitting diodes coupled to each other.

12. The light emitting element as claimed in claim 11, wherein each of the light emitting diodes comprises:
a first semiconductor layer;
a light emitting layer disposed on the first semiconductor layer;
a second semiconductor layer disposed on the light emitting layer;
a first electrode disposed on the first semiconductor layer; and
a second electrode disposed on the second semiconductor layer;
wherein dielectric layers are disposed between the light emitting diodes, and the second electrode of one of the light emitting diodes is coupled to the first electrode of its adjacent light emitting diodes.

13. The light emitting element as claimed in claim 12, wherein the first semiconductor layer is disposed on the first substrate, and the selective reflection layer is disposed on the second semiconductor layer, the first electrode and the second electrode.

14. The light emitting element as claimed in claim 13 further comprising a reflection layer disposed on the first semiconductor layer.

15. The light emitting element as claimed in claim 12, wherein the first and second electrodes are coupled to the first substrate through a metal contact, the selective reflection layer is disposed on the first semiconductor layer, and a second substrate is disposed between the first semiconductor layer and the selective reflection layer.

16. The light emitting element as claimed in claim 15 further comprising a reflection layer disposed on the second semiconductor layer.

17. The light emitting element as claimed in claim 1, wherein the first substrate is in a shape of a bowl.
